(19) United States
(12) Patent Application Publication
(10) Pub. No.: US 2026/0006995 A1
(43) Pub. Date: Jan. 1, 2026

(54) DISPLAY PANEL AND MANUFACTURING METHOD THEREFOR, AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Yige QI, Beijing (CN); Chao KONG, Beijing (CN); Tiancheng YU, Beijing (CN); Ruqin ZHANG, Beijing (CN); Pingchuan ZENG, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 18/993,004

(22) PCT Filed: Jul. 20, 2023
(86) PCT No.: PCT/CN2023/108436

§ 371 Date: Jan. 10, 2025

(30) Foreign Application Priority Data
Jul. 22, 2022 (CN) 202210871509.8

(51) Int. Cl. H10K 59/122; H10K 59/12; H10K 59/80

(52) U.S. Cl. CPC H10K 59/122; H10K 59/1201; H10K 59/873; H10K 59/879

(57) ABSTRACT

An optical path regulation layer is located on the side of an encapsulation layer of the display panel away from a driving backplane. The optical path regulation layer includes a first refractive unit and a second refractive unit. The refractive index of the second refractive unit is greater than the refractive index of the first refractive unit. The orthographic projection of the first refractive unit or the second refractive unit on the driving backplane covers the orthographic projection of at least one sub-pixel on a base substrate. After an exit light of the sub-pixel passes through an interface between the side surface of the first refractive unit and the side surface of the second refractive unit, the exit angle of the exit light is increased or decreased.

### CROSS-REFERENCE TO RELATED APPLICATION(S)

The present disclosure is a U.S. National Stage of International Application No. PCT/CN2023/108436 filed on Jul. 20, 2023, which claims priority to Chinese patent application No. 202210871509.8 filed on Jul. 22, 2022 and entitled “Display panel, manufacturing method therefor, and display device”, the disclosure of both are incorporated herein by reference in their entireties.

### TECHNICAL FIELD

The present disclosure relates to the field of display technology, and in particular to a display panel and a manufacturing method therefor, and a display device.

### BACKGROUND

Flexible Multi-Layer On Cell (FMLOC) design is currently mainstream in the field of OLED touch display. FMLOC design refers to manufacturing a metal electrode layer on the encapsulation layer of the display substrate, where the surface of the metal electrode layer significantly reflects ambient light.

In order to reduce ambient light reflection and improve contrast, a black matrix is introduced to absorb light in non-pixel areas. Due to differences in shape and size of different sub-pixels, the black matrix has different effects on the luminance of light of different colors, causing color deviation in the display panel.

It should be noted that the information disclosed in the above Background section is only used to enhance understanding of the background of the present disclosure, and therefore may include information that does not constitute prior art known to those of ordinary skills in the art.

### SUMMARY

The present disclosure provides a display panel and a manufacturing method therefor, and a display device.

According to an aspect of the present disclosure, a display panel is provided, including a driving backplane, a pixel layer, an encapsulation layer, and an optical path regulation layer. The pixel layer includes a pixel definition layer and a plurality of sub-pixels of different colors. The pixel definition layer is located on a side of the driving backplane. The pixel definition layer is provided with a plurality of pixel openings. The plurality of sub-pixels is respectively located in different pixel openings. The encapsulation layer is located on a side of the pixel layer away from the driving backplane. The optical path regulation layer is located on a side of the encapsulation layer away from the driving backplane. The optical path regulation layer includes a plurality of first refractive units. The angle between the side surface and the bottom surface of the first refractive unit is greater than or less than 90 degrees. A second refractive unit is arranged between two adjacent first refractive units. The orthographic projection of the first refractive unit or the second refractive unit on the driving backplane covers the orthographic projection of at least one sub-pixel on the driving backplane. The refractive index of the second refractive unit is greater than the refractive index of the first refractive unit. After the exit light of the sub-pixel passes through the interface between the side surface of the first refractive unit and the side surface of the second refractive unit, the exit angle of the exit light becomes larger or smaller.

In an embodiment of the present disclosure, the display panel further includes a color filter layer. The color filter layer is located on a side of the encapsulation layer away from the driving backplane. The light path regulation layer is located on a side of the color filter layer away from and/or close to the driving backplane. The color filter layer includes filter units of different colors and a black matrix located at a periphery of the filter unit. The orthographic projection of the filter unit of a color on the driving backplane covers the orthographic projection of the first refractive unit or the second refractive unit corresponding to the sub-pixel of the same color on the driving backplane.

In an embodiment of the present disclosure, the light path regulation layer includes a first light path regulation layer. The first light path regulation layer is located on a side of the color filter layer close to the driving backplane. The orthographic projection of the second refractive unit of the first light path regulation layer on the driving backplane covers the orthographic projection of at least one sub-pixel on the driving backplane. The angle between the side surface and the bottom surface of the first refractive unit of the first light path regulation layer is less than 90 degrees.

In an embodiment of the present disclosure, the optical path regulation layer includes a first optical path regulation layer. The first optical path regulation layer is located on a side of the color filter layer close to the driving backplane. The orthographic projection of the second refractive unit of the first optical path regulation layer on the driving backplane covers the orthographic projection of at least one sub-pixel on the driving backplane. The angle between the side surface and the bottom surface of the first refractive unit of the first optical path regulation layer is greater than 90 degrees.

In an embodiment of the present disclosure, the optical path regulation layer includes a second optical path regulation layer. The second optical path regulation layer is located on a side of the color filter layer away from the driving backplane. The orthographic projection of the second refractive unit of the second optical path regulation layer on the driving backplane covers the orthographic projection of at least one sub-pixel on the driving backplane. The angle between the side surface and the bottom surface of the first refractive unit of the second optical path regulation layer is less than 90 degrees.

In an embodiment of the present disclosure, the optical path regulation layer includes a second optical path regulation layer. The second optical path regulation layer is located on a side of the color filter layer away from the driving backplane. The orthographic projection of the second refractive unit of the second optical path regulation layer on the driving backplane covers the orthographic projection of at least one sub-pixel on the driving backplane. The angle between the side surface and the bottom surface of the first refractive unit of the second optical path regulation layer is greater than 90 degrees. The angle between the exit light and the normal line of the side surface of the first refractive unit of the second optical path regulation layer is less than 40 degrees.

In an embodiment of the present disclosure, the optical path regulation layer includes a second optical path regulation layer. The second optical path regulation layer is located on a side of the color filter layer away from the driving backplane. The orthographic projection of the second refractive unit of the second optical path regulation layer on the driving backplane covers the orthographic projection of at least one sub-pixel on the driving backplane. The angle between the side surface and the bottom surface of the first refractive unit of the second optical path regulation layer is greater than 90 degrees. The angle between the exit light and the normal line of the side surface of the first refractive unit of the second optical path regulation layer is greater than 40 degrees and less than 90 degrees.

In an embodiment of the present disclosure, the optical path regulation layer includes a second optical path regulation layer. The second optical path regulation layer is located on a side of the color filter layer away from the driving backplane. The orthographic projection of the first refractive unit of the second optical path regulation layer on the driving backplane covers the orthographic projection of at least one sub-pixel on the driving backplane. The angle between the side surface and the bottom surface of the first refractive unit of the second optical path regulation layer is less than 90 degrees.

In an embodiment of the present disclosure, the first optical path regulation layer is a touch layer. The touch layer includes a plurality of touch groups, and the plurality of touch groups is respectively wrapped in the plurality of first refractive units.

In an embodiment of the present disclosure, the distance between the edge of the orthographic projection of the touch group on the driving backplane and the edge of the orthographic projection of the first refractive unit on the driving backplane is greater than 2 microns.

In an embodiment of the present disclosure, the distance between the edge of the orthographic projection on the driving backplane of the side with a smaller width of the second refractive unit and the edge of the orthographic projection on the driving backplane of the side away from the driving backplane of the sub-pixel is greater than 5 microns.

In an embodiment of the present disclosure, the refractive index of the first refractive unit is 1.3-1.5, and the refractive index of the second refractive unit is 1.7-1.9.

In an embodiment of the present disclosure, the material of the first refractive unit is positive photoresist or negative photoresist.

In an embodiment of the present disclosure, the thickness of the second refractive unit is greater than the thickness of the first refractive unit, the sides of the second refractive units close to the driving backplane are located on the same plane, the side of the second refractive unit away from the driving backplane is higher than the first refractive unit, and two adjacent second refractive units are connected and cover the side of the first refractive unit away from the driving backplane.

In an embodiment of the present disclosure, the thickness of the first refractive unit is 2-3 microns, and the thickness of the second refractive unit is 3-5 microns.

In an embodiment of the present disclosure, the touch layer includes a first touch layer and a second touch layer. The first passivation layer is provided on a side of the first touch layer away from the driving backplane. The second passivation layer is provided on a side of the second touch layer away from the driving backplane. The first touch layer includes a first touch part, the second touch layer includes a second touch part, and the first touch part and the second touch part constitute the touch group.

According to another aspect of the present disclosure, a display device is provided, including a display panel according to an aspect of the present disclosure.

According to another aspect of the present disclosure, a method for manufacturing a display panel is provided, the manufacturing method comprising: providing a driving backplane;
forming a pixel layer on a side of the driving backplane, where the pixel layer includes a pixel definition layer and a plurality of sub-pixels, the pixel definition layer is provided with a plurality of pixel openings, and the plurality of sub-pixels is respectively provided in different pixel openings;
forming an encapsulation layer on a side of the pixel layer away from the driving backplane; and
forming a first refractive layer on a side of the encapsulation layer away from the driving backplane, patterning the first refractive layer to form a plurality of first refractive units, and filling a second refractive layer between two adjacent first refractive units to form a plurality of second refractive units, where the orthographic projection of the first refractive unit or the second refractive unit on the driving backplane covers the orthographic projection of at least one sub-pixel on the driving backplane.

In an embodiment of the present disclosure, the first refractive layer is positive photoresist, and patterning the first refractive layer to form the plurality of first refractive units includes: exposing and developing the area of the first refractive layer directly facing the sub-pixel to form the plurality of first refractive units, where the angle between the side surface and the bottom surface of the first refractive unit is less than 90 degrees.

In an embodiment of the present disclosure, the first refractive layer is negative photoresist, and patterning the first refractive layer to form the plurality of first refractive units includes: exposing and developing the area of the first refractive layer directly facing the pixel definition layer at a periphery of the sub-pixel to form the plurality of first refractive units, where the angle between the side surface and the bottom surface of the first refractive unit is greater than 90 degrees.

It should be understood that the above general description and the detailed description below are only examples and explanatory, and cannot limit the present disclosure.

### BRIEF DESCRIPTION OF THE DRAWINGS

The drawings herein are incorporated into the specification and constitute a part of the specification, showing embodiments consistent with the present disclosure, and are used together with the specification to explain the principles of the present disclosure. It shall be noted that the drawings described below are only some embodiments of the present disclosure. For those of ordinary skills in the art, other drawings can also be obtained based on these drawings without creative work.

FIG. 1 is a schematic structural diagram of a display panel without an optical path regulation layer according to an embodiment of the present disclosure.

FIG. 2 is a top view of a touch layer according to an embodiment of the present disclosure.

FIG. 3 is a cross-sectional view along A-A of FIG. 2.

FIG. 4 is a schematic structural diagram of a display panel in which the angle between the side surface and the bottom surface of the first refractive unit is less than 90 degrees according to an embodiment of the present disclosure.

FIG. 5 is a schematic structural diagram of a display panel in which the angle between the side surface and the bottom surface of the first refractive unit is greater than 90 degrees according to an embodiment of the present disclosure.

FIG. 6 is a schematic structural diagram of a display panel for slowing down the luminance decay at full viewing angle according to an embodiment of the present disclosure.

FIG. 7 is a schematic structural diagram of a display panel for accelerating the luminance decay at full viewing angle according to an embodiment of the present disclosure.

FIG. 8 is a schematic structural diagram of a display panel for regulating the luminance decay at a specific viewing angle according to an embodiment of the present disclosure.

FIG. 9 is a curve showing the relationship between the viewing angle and luminance of the display panel in FIG. 8.

FIG. 10 is a schematic structural diagram of a display panel for accelerating the luminance decay at a small viewing angle according to an embodiment of the present disclosure.

FIG. 11 is a schematic structural diagram of another display panel for accelerating the luminance decay at a small viewing angle according to an embodiment of the present disclosure.

FIG. 12 is a curve showing the relationship between the viewing angle and luminance of the display panel in FIG. 10 and FIG. 11.

FIG. 13 is a schematic structural diagram of a display panel for slowing down the luminance decay at a small viewing angle according to an embodiment of the present disclosure.

FIG. 14 is a schematic structural diagram of another display panel for slowing down the luminance decay at a small viewing angle according to an embodiment of the present disclosure.

FIG. 15 is a curve showing the relationship between the viewing angle and luminance of the display panel in FIG. 13 and FIG. 14.

FIG. 16 is a schematic structural diagram of a display panel for slowing down the luminance decay at a large viewing angle according to an embodiment of the present disclosure.

FIG. 17 is a schematic structural diagram of another display panel for slowing down the luminance decay at a large viewing angle according to an embodiment of the present disclosure.

FIG. 18 is a curve showing the relationship between the viewing angle and luminance of the display panel in FIG. 16 and FIG. 17.

FIG. 19 is a schematic structural diagram of a display panel for accelerating the luminance decay at a large viewing angle according to an embodiment of the present disclosure.

FIG. 20 is a schematic structural diagram of another display panel for accelerating the luminance decay at a large viewing angle according to an embodiment of the present disclosure.

FIG. 21 is a curve showing the relationship between the viewing angle and luminance of the display panel in FIG. 19 and FIG. 20.

FIG. 22 is a schematic structural diagram of a display panel for slowing down the blueing effect at a large viewing angle according to an embodiment of the present disclosure.

FIG. 23 is a CIE trajectory diagram at the white light viewing angle of the display panel in FIG. 22.

FIG. 24 is a schematic diagram of the color deviation at different viewing angles of the display panel in FIG. 22.

FIG. 25 is a schematic structural diagram of a display panel for slowing down the blueing effect at a small viewing angle and the yellowing effect at a large viewing angle according to an embodiment of the present disclosure.

FIG. 26 is a CIE trajectory diagram at the white light viewing angle of the display panel in FIG. 25.

FIG. 27 is a schematic diagram of the color deviation at different viewing angles of the display panel in FIG. 25.

FIG. 28 is a schematic structural diagram of a display substrate according to an embodiment of the present disclosure.

FIG. 29 is a flow chart of a method for manufacturing a display substrate according to an embodiment of the present disclosure.

In the drawings:

10—driving backplane, 11—base substrate, 12—first buffer layer; 13—driving circuit layer, 131—active layer, 132—gate insulation layer, 133—gate, 134—interlayer insulation layer, 135—interlayer dielectric layer, 1361—first source, 1362—drain, 137—protective layer, 1381—second source; 14—planarization layer group, 141—first planarization layer, 142—second planarization layer; 20—pixel layer, 201—pixel definition layer, 2011—pixel opening, 202—sub-pixel, 2021—pixel electrode, 2022—light-emitting layer, 2023—common electrode, 2024—red sub-pixel, 2025—green sub-pixel, 2026—blue sub-pixel; 30—encapsulation layer, 31—first inorganic encapsulation layer, 32—organic encapsulation layer, 33—second inorganic encapsulation layer; 40—light path regulation layer, 41—first light path regulation layer, 42—second light path regulation layer, 401—first refractive unit, 402—second refractive unit, 50—color filter layer, 51—filter unit, 511—red filter unit, 512—green filter unit, 513—blue filter unit, 52—black matrix; 60—touch layer, 61—first touch layer, 611—first touch part, 612—bridge part, 62—second touch layer, 621—second touch part, 622—touch driving metal grid, 623—touch sensing metal grid, 63—first passivation layer, 64—second passivation layer, 65—second buffer layer, 66—touch group, 67—driving lead.

### DETAILED DESCRIPTION OF THE EMBODIMENTS

Example embodiments will now be described more fully with reference to the accompanying drawings. However, example embodiments can be implemented in a variety of forms and should not be construed as limited to the embodiments set forth herein. Rather, these embodiments are provided, so that the present disclosure will be comprehensive and complete, and the concepts of the example embodiments will be fully conveyed to those skilled in the art. The same reference numerals in the drawings represent the same or similar structures, and their detailed descriptions will be omitted. In addition, the drawings are only schematic illustrations of the present disclosure and are not necessarily drawn to scale.

Although relative terms such as “upper” and “lower” are used in the specification to describe the relationship of one component represented by an icon relative to another component, these terms are used in the specification only for convenience, such as according to the example direction described in the drawings. It is understood that if the device represented by the icon is flipped so that it is upside down, the component described as “upper” will become the component “lower”. When a structure is “on” another structure, it may mean that a structure is formed integrally on the other structure, or that a structure is “directly” set on the other structure, or that a structure is “indirectly” set on the other structure through an intermediate structure.

The terms “one”, “an”, “the”, “said” and “at least one” are used to indicate the presence of one or more elements or components, etc. The terms “including” and “having” are used to indicate an open-ended inclusion, and mean that there may be other elements or components, etc. in addition to the listed elements or components, etc. The terms “first”, “second” and “third” are used only as markers and are not limiting the number of the relevant objects.

The Active Matrix Organic Light Emitting Devices (AMOLED) have the advantages of low power consumption and flexible display. A flexible multilayer structure (also called as Functional Metal Layer On Cell, FMLOC) may be directly formed on the display panel. That is, a metal electrode layer is made on the encapsulation layer of the display panel for touch purpose. The flexible multilayer structure can reduce the thickness of the screen, which is conducive to folding. At the same time, there is no fitting tolerance, which can reduce the frame width. FMLOC contains two metal layers, and the surface of the metal electrode layer reflects ambient light significantly. In order to reduce the reflection of ambient light on the surface of the metal electrode layer and improve the contrast of the displayed image, a color filter layer (also called as Color filter On Encapsulation, COE) is provided on the side of the flexible multilayer structure away from the display substrate.

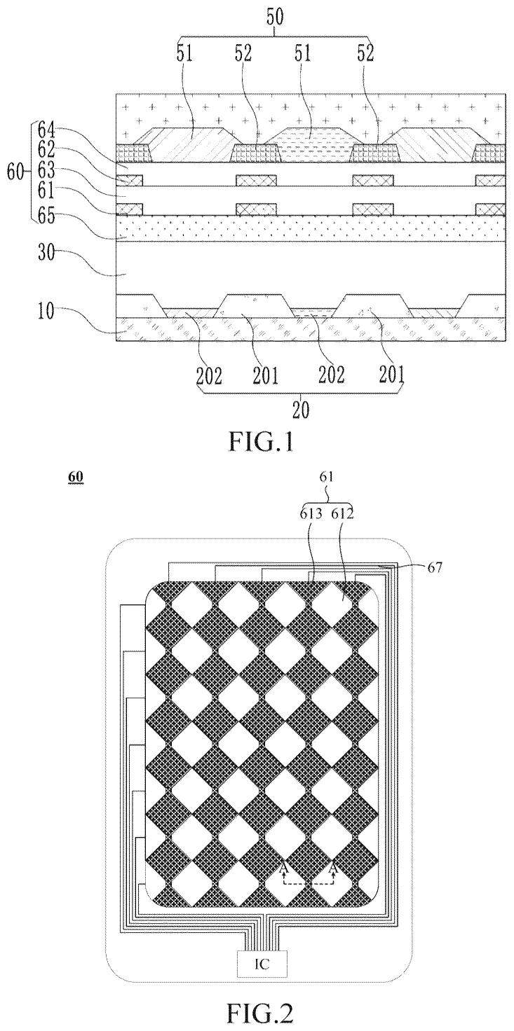

FIG. 1 is a cross-sectional view of an OLED display panel integrating FMLOC and COE in the related art. The display panel includes a driving backplane 10 (also called as backing plate, BP). A pixel layer 20 is provided on the driving side of the driving backplane 10. The pixel layer 20 includes a pixel definition layer (PDL) provided with pixel openings. OLED light-emitting devices of different colors are provided in the pixel openings. A thin film encapsulation layer (TFE) is provided on the side of the pixel layer 20 away from the driving backplane 10. A flexible multilayer structure (also called as Functional Metal Layer On Cell, FMLOC,) is provided on the side of the thin film encapsulation layer away from the driving backplane 10. A color filter layer 50 (also called as Color filter On Encapsulation, COE) is provided on the side of the flexible multilayer structure away from the driving backplane 10.

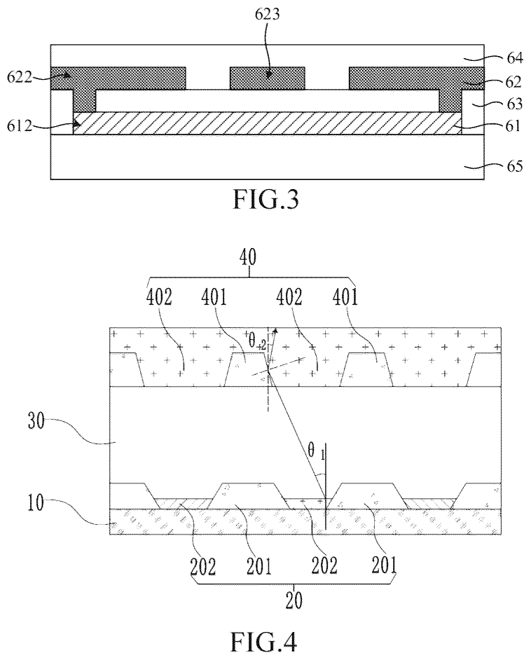

As shown in FIG. 2 and FIG. 3, the flexible multilayer structure generally refers to a touch layer 60, and the touch layer 60 may be a mutual capacitance touch. The touch layer 60 includes a first touch layer 61 and a second touch layer 62. The first passivation layer 63 is provided on the side of the first touch layer 61 away from the base substrate 11. The second passivation layer 64 is provided on the side of the second touch layer 62 away from the base substrate 11. The second buffer layer 65 may also be provided between the encapsulation layer and the first touch layer 61.

The second touch layer 62 may be a Metal Mesh (MM). The first touch layer 61 may be a Bridge Metal layer (BM). The second touch layer 62 may also be a Bridge Metal layer (BM). The first touch layer 61 may be a Metal Mesh layer (MM).

The following description assumes that the second touch layer 62 is a Metal Mesh layer (MM) and the first touch layer 61 is a Bridge Metal layer (BM). The second touch layer 62 may be divided into touch driving metal grids 622 and touch sensing metal grids 623 in the horizontal and vertical directions. The touch sensing metal grids 623 are connected to each other, and the touch driving metal grids 622 are connected through the bridge part 612 of the first touch layer 61. Alternatively, the touch driving metal grids 622 are connected to each other, and the touch sensing metal grids 623 are connected through the bridge part 612 of the first touch layer 61. The touch driving metal grids 622 located in the same row, and respectively the touch sensing metal grids 623 located in the same column, are connected to the driving IC through the driving lead 67.

It should be noted that the thickness of the buffer layer is usually 0.3˜1 micron, the thickness of the first passivation layer 63 is usually 0.3˜1 micron, and the thickness of the second passivation layer 64 is usually 2˜3 microns. The materials of the buffer layer, the first passivation layer, and the second passivation layer may all be polyimide (PI).

The second touch layer 62 may be composed of a first titanium metal layer, an aluminum metal layer, and a second titanium metal layer arranged in sequence in a direction away from the driving backplane 10. The thickness of the first titanium metal layer may be 0.03 microns, the thickness of the aluminum metal layer may be 0.3 microns, and the thickness of the first titanium metal layer may be 0.03 microns. The layer structure and thickness of each layer of the first touch layer 61 and the second touch layer 62 may be the same, so they are not repeated.

The color filter layer 50 includes a filter unit 51 arranged in the pixel area and a black matrix (BM) arranged in the non-pixel area. The orthographic projection of the filter unit 51 of a color on the driving backplane 10 covers the orthographic projection of the second refractive unit 402 corresponding to the sub-pixel of the same color on the driving backplane 10. A protective layer may also be arranged on the side of the color filter layer 50 away from the driving backplane 10. The protective layer covers the filter unit 51 and the black matrix. The thickness of the black matrix 52 is usually 1.3 microns, the thickness of the filter unit 51 is usually 3 microns, and the thickness of the protective layer is usually 2˜3 microns.

The black matrix will cause the luminance decay (L-Decay) of the exit light of the sub-pixel to increase with the increase of the viewing angle. Due to the difference in shape and size of RGB sub-pixels of different colors, the degrees of aggravation of the luminance decay caused by the black matrix of the RGB sub-pixels of different colors at different viewing angles are usually inconsistent, resulting in a mismatch in the luminance decay of the RGB sub-pixels of different colors at different viewing angles, and the color deviation of the displayed image at the white light viewing angle.

In the related art, one regulation method is to control the microcavity length and/or cathode reflectivity of the OLED device; and another regulation method is to choose the opening size of the black matrix around the sub-pixels of different colors in a differentiated manner. The above two regulation methods are usually used to control the luminance decay of the monochromatic light at full viewing angle, and cannot control the luminance decay of the monochromatic light in a specific angle range. When it is necessary to optimize the color deviation trajectory and color deviation value of white light in a specific viewing angle range (such as a small viewing angle or a large viewing angle), the color deviation of white light in other viewing angle ranges is often degraded.

The following is an explanation of the other regulation method. When the opening size of the black matrix is ≥4 microns, the aggravation of the luminance decay at a small viewing angle is significantly reduced. But, in order to reduce the reflectivity, the opening size of the black matrix is usually controlled at 1.5˜3 microns, which will still significantly accelerate the luminance decay at a small viewing angle.

In view of above, an embodiment of the present disclosure provides a display panel. As shown in FIGS. 4 to 28, the display panel includes a driving backplane 10, a pixel layer 20, an encapsulation layer, a color filter layer 50, and an optical path regulation layer 40. The pixel layer 20 includes a pixel definition layer and a plurality of sub-pixels of different colors. The pixel definition layer is located on a side of the driving backplane 10. The pixel definition layer is provided with a plurality of pixel openings. The plurality of sub-pixels is respectively located in different pixel openings. The encapsulation layer is located on the side of the pixel layer 20 away from the driving backplane 10. The color filter layer 50 is located on the side of the encapsulation layer away from the driving backplane 10. The color filter layer 50 includes filter units 51 of different colors and a black matrix 52 located at the periphery of the filter unit 51. The orthographic projection of the filter unit 51 of a color on the driving backplane 10 covers the orthographic projection of the sub-pixel of the same color on the driving backplane 10. The light path regulation layer 40 is located on the side of the encapsulation layer away from the driving backplane 10. The light path regulation layer 40 includes a plurality of first refractive units 401. The angle between the side surface and the bottom surface of the first refractive unit 401 is greater than or less than 90 degrees. The second refractive unit 402 is arranged between two adjacent first refractive units 401. The orthographic projection of the first refractive unit 401 or the second refractive unit 402 on the driving backplane 10 covers the orthographic projection of at least one sub-pixel on the base substrate. The refractive index of the second refractive unit 402 is greater than the refractive index of the first refractive unit 401. After the exit light of the sub-pixel passes through the interface between the side surface of the first refractive unit 401 and the side surface of the second refractive unit 402, the exit angle of the exit light becomes larger or smaller.

The optical path regulation layer 40 is provided on the side of the encapsulation layer of the display panel away from the driving backplane 10. The optical path regulation layer 40 includes a first refractive unit 401 and a second refractive unit 402. The refractive index of the second refractive unit 402 is greater than the refractive index of the first refractive unit 401. The orthographic projection of the first refractive unit 401 or the second refractive unit 402 on the driving backplane 10 covers the orthographic projection of at least one sub-pixel on the base substrate. After the exit light of the sub-pixel passes through the interface between the side surface of the first refractive unit 401 and the side surface of the second refractive unit 402, the exit angle of the exit light becomes larger or smaller. Thereby, the luminance decay of a certain monochromatic light is accelerated or slowed down, thereby improving the color deviation of the display panel.

It should be noted that the refractive index of the first refractive unit 401 is generally 1.3-1.5, and the refractive index of the second refractive unit 402 is generally 1.7-1.8.

From the perspective of the structural strength of the optical path regulation layer 40 and the manufacturing process therefor, two adjacent second refractive units 402 may be connected to cover the side of the first refractive unit 401 away from the driving backplane 10. When forming the second refractive unit 402, it is sufficient to directly fill up between two adjacent refractive units. Therefore, the thickness of the second refractive unit 402 is greater than that of the first refractive unit 401. Specifically, the thickness of the first refractive unit 401 may be 2-3 microns, and the thickness of the second refractive unit 402 may be 3-5 microns. The sides of the second refractive units 402 close to the driving backplane 10 are located on the same plane. The height of the side of the second refractive unit 402 away from the driving backplane 10 is higher than that of the first refractive unit 401.

The material of the first refractive unit 401 is positive photoresist or negative photoresist. When the material of the first refractive unit 401 is positive photoresist, the exposure area is an area of the first refractive layer directly facing the sub-pixel, and the residue increases with the increase of etching depth during the development and patterning process, so that the cross section of the first refractive unit 401 is a positive trapezoid. That is, the angle between the side surface and the bottom surface of the first refractive unit 401 is less than 90 degrees. When the material of the first refractive unit 401 is negative photoresist, the exposure area is an area of the first refractive layer directly facing the pixel definition layer at the periphery of the sub-pixel. As the etching depth increases during the development process, the loss of the film layer to be retained increases, resulting in the cross-section of the first refractive unit 401 being an inverted trapezoid. That is, the angle between the side surface and the bottom surface of the first refractive unit 401 is greater than 90 degrees.

As shown in FIG. 4, when the angle between the side surface and the bottom surface of the first refractive unit 401 is less than 90 degrees, and the light emitted by the sub-pixel passes through the second refractive unit 402 and reaches the side surface of the first refractive unit 401, total reflection will occur at the interface between the second refractive unit 402 and the first refractive unit 401 if the incident angle θ1 is greater than the critical angle. This is because the angle between the normal line of the side surface of the first refractive unit 401 and the horizontal direction is positive, and the exit angle θ2 of the exit light is greater than the incident angle θ1. Thus, the converging effect of the exit light will be generated, thereby accelerating the luminance decay of the light emitted by the corresponding sub-pixel.

As shown in FIG. 5, when the angle between the side surface and bottom surface of the first refractive unit 401 is less than 90 degrees, and the light emitted by the sub-pixel passes through the second refractive unit 402 and reaches the side surface of the first refractive unit 401, total reflection will also occur at the interface between the second refractive unit 402 and the first refractive unit 401 if the incident angle θ1 is greater than the critical angle. This is because the angle between the normal line of the side surface of the first refractive unit 401 and the horizontal direction is negative, the exit angle θ2 of the exit light is less than the incident angle θ1. Thus, the diverging effect of the exit light will be generated, thereby slowing down the luminance decay of the light emitted by the corresponding sub-pixel.

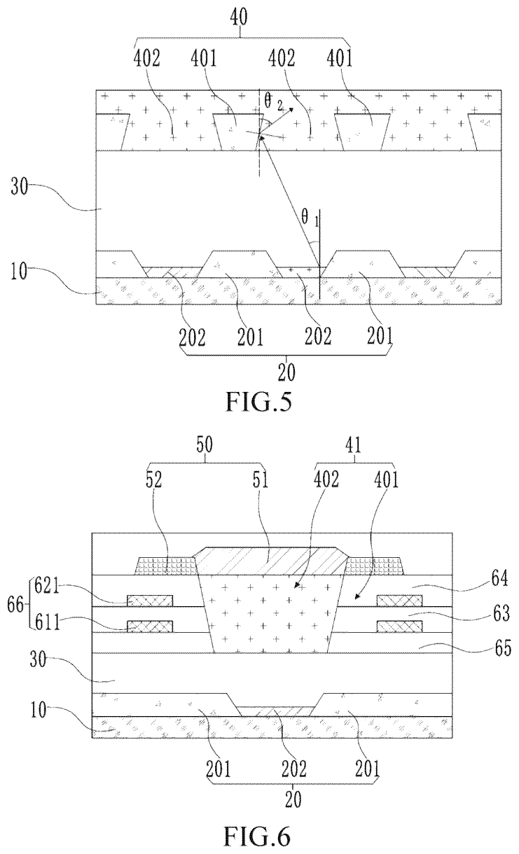

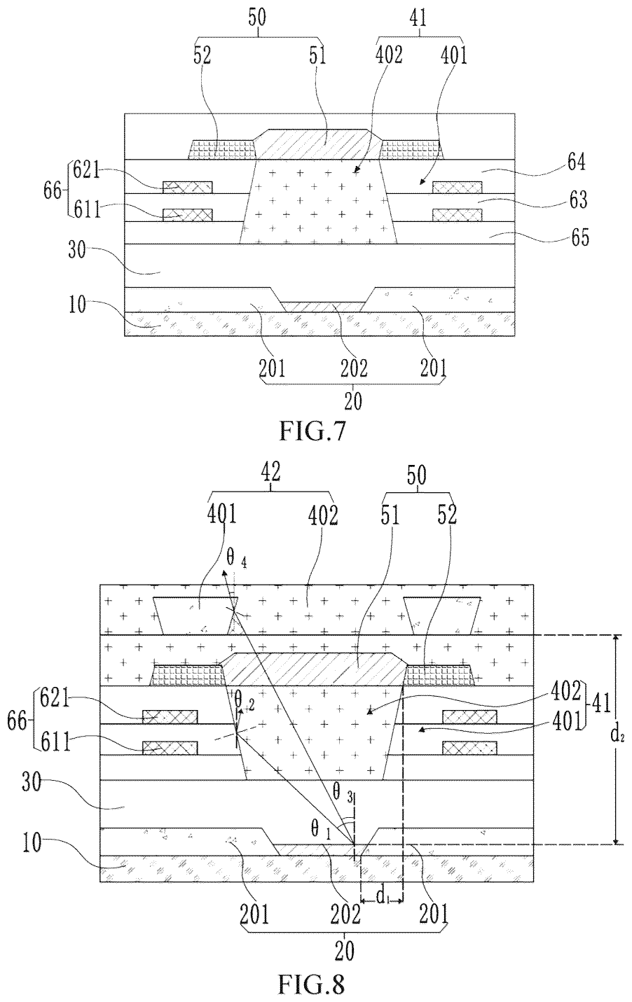

As shown in FIG. 6 and FIG. 7, the display panel also includes a color filter layer 50, which is arranged on the side of the encapsulation layer away from the driving backplane 10. The optical path regulation layer may be arranged on the side of the color filter layer 50 close to the driving backplane 10, or on the side of the color filter layer 50 away from the driving backplane 10. The color filter layer 50 may include filter units 51 of different colors and a black matrix 52 disposed at the periphery of the filter unit 51. The orthographic projection of the filter unit 51 of a color on the driving backplane 10 covers the orthographic projection of the first refractive unit 401 or the second refractive unit 402 corresponding to the sub-pixel of the same color on the driving backplane 10.

As shown in FIG. 6, the optical path regulation layer includes a first optical path regulation layer 41, which is disposed on the side of the color filter layer 50 close to the driving backplane 10. The orthographic projection of the second refractive unit 402 of the first optical path regulation layer 41 on the driving backplane 10 covers the orthographic projection of at least one sub-pixel on the base substrate. The angle between the side surface and the bottom surface of the first refractive unit 401 is less than 90 degrees. After the exit light of the corresponding sub-pixel converges through the first optical path regulation layer 41, it is emitted from the filter unit 51 of the same color. The luminance decay of a certain monochromatic light at full viewing angle can be accelerated.

As shown in FIG. 7, the optical path regulation layer includes a first optical path regulation layer 41, which is disposed on the side of the color filter layer 50 close to the driving backplane 10. The orthographic projection of the second refractive unit 402 of the first optical path regulation layer 41 on the driving backplane 10 covers the orthographic projection of at least one sub-pixel on the base substrate. The angle between the side surface and bottom surface of the first refractive unit 401 of the first optical path regulation layer 41 is greater than 90 degrees. The light emitted by the corresponding sub-pixel is diverged through the first optical path regulation layer 41 and then emitted from the filter unit 51 of the same color. The luminance decay of a certain monochromatic light at full viewing angle can be slowed down.

The first optical path regulation layer 41 is a touch layer. The first touch layer and the second touch layer of the touch layer are usually arranged in the non-pixel area. The first touch layer includes a first touch part 611, and the second touch layer includes a second touch part 621. The first touch part 611 and the second touch part 621 between two adjacent sub-pixels are defined as the touch group 66. The first passivation layer and the second passivation layer between two adjacent touch groups 66 are patterned to form a plurality of first refractive units 401. The plurality of touch groups 66 is respectively wrapped in the plurality of first refractive units 401.

The first optical path regulation layer is set by using an existing film layer, which reduces the increase in thickness of the display panel while realizing the luminance regulation of the display panel. It should be noted that in other feasible implementations, the first optical path regulation layer may also be set separately.

The width of the touch group 66 is usually 3 microns. Considering the accuracy of the etching process, the width of the first refractive unit 401 is usually greater than or equal to 7 microns. Specifically, the distance between the edge of the orthographic projection of the touch group 66 on the driving backplane 10 and the edge of the orthographic projection of the first refractive unit 401 on the driving backplane 10 is greater than 2 microns. The refraction effect of the first refractive unit 401 can be ensured without affecting the touch function of the touch layer.

The spacing between adjacent sub-pixels is usually 18-23 microns, so that the side with a smaller width of the second refractive unit 402 can be expanded by more than 10 microns than the light-emitting area of the sub-pixel. Generally, the center line of the sub-pixel is coinciding with the center line of the second refractive unit 402. Therefore, it is usually that the distance between the edge of the orthographic projection on the driving backplane of the side with a smaller width of the second refractive unit 402 and the edge of the orthographic projection on the driving backplane 10 of the side away from the driving backplane 10 of the sub-pixel is greater than 5 microns. This effectively ensures that the exit light of the sub-pixel area is incident into the second refractive unit 402 first.

As shown in FIG. 8, on the basis of FIG. 6, a second optical path regulation layer 42 may be further provided on the side of the color filter layer 50 away from the driving backplane 10. Because the second optical path regulation layer 42 is moved upward relative to the first optical path regulation layer 41, and the vertical distance d2 from the sub-pixel is farther, the viewing angle required for the same point of the sub-pixel to reach the regulation interface of the second optical path regulation layer 42 is significantly reduced. Therefore, the first optical path regulation layer 41 will accelerate the luminance decay at the full viewing angle) (0˜80°, while the regulation viewing angle of the second optical path regulation layer 42 will be reduced, which can accelerate the luminance decay at a small viewing angle.

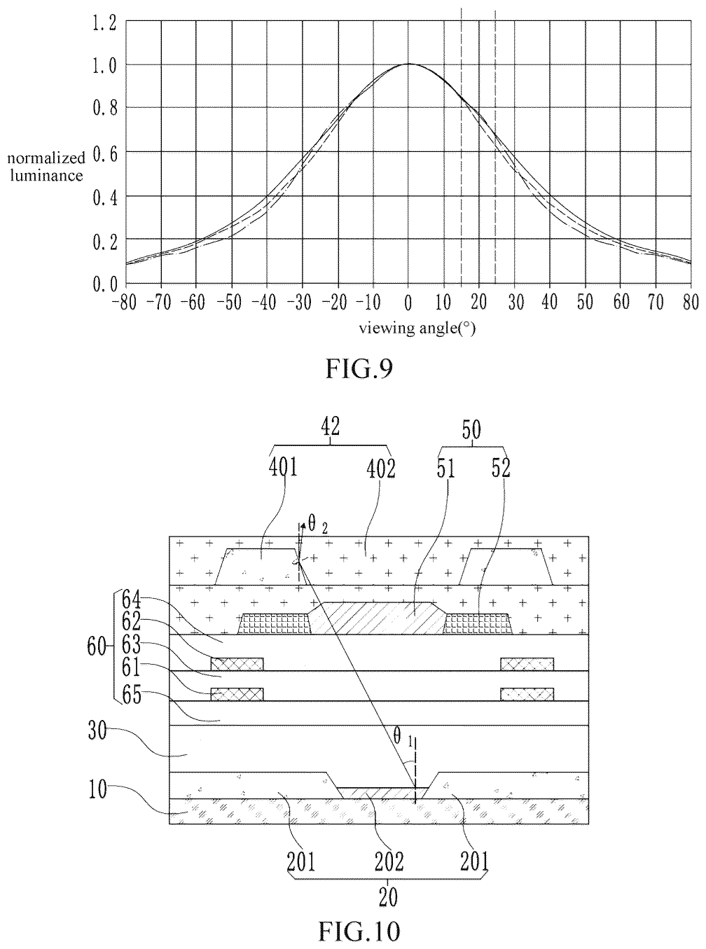

The size of the second refractive unit 402 of the second optical path regulation layer 42 may be adjusted, or the vertical distance d2 between the second optical path regulation layer 42 and the sub-pixel may be adjusted, and the horizontal distance dl between the second optical path regulation layer 42 and the sub-pixel may also be adjusted, so as to further reduce the regulation viewing angle of the second optical path regulation layer 42, so that the second optical path regulation layer 42 only regulates the luminance decay in a specific small viewing angle range. As shown in FIG. 9, the solid line is the curve of luminance variation with viewing angle when the first optical path regulation layer 41 and the second optical path regulation layer 42 are not provided; the dashed line is the curve of luminance variation with viewing angle when only the first optical path regulation layer 41 is provided; and the dotted line is the curve of luminance variation with viewing angle when both the first optical path regulation layer 41 and the second optical path regulation layer 42 are provided. It can be seen that when only the first optical path regulation layer 41 is provided, the display luminance decays at full viewing angle; and when the first optical path regulation layer 41 and the second optical path regulation layer 42 are both provided, the display luminance decays at full viewing angle, and decays fastest in 15°-25°.

As shown in FIG. 10, the second optical path regulation layer 42 may also be provided on the side of the color filter layer 50 away from the driving backplane 10. The orthographic projection of the second refractive unit 402 of the second optical path regulation layer 42 on the driving backplane 10 covers the orthographic projection of at least one sub-pixel on the base substrate. The angle between the side surface and bottom surface of the first refractive unit 401 of the second optical path regulation layer 42 is less than 90 degrees. Compared with the first light path regulation layer 41, the second light path regulation layer 42 is at a farther vertical distance d2 from the sub-pixel, and the incident angle θ1 is greater than the critical angle. Therefore, the exit light of the sub-pixel will undergo total reflection when being incident onto the side surface of the first refractive unit 401, so that the exit angle θ2 of the exit light becomes smaller, and the viewing angle required for the same sub-pixel to reach the side surface of the second light path regulation layer 42 is significantly reduced. Thereby, the luminance decay of a certain monochromatic light at a small viewing angle is accelerated.

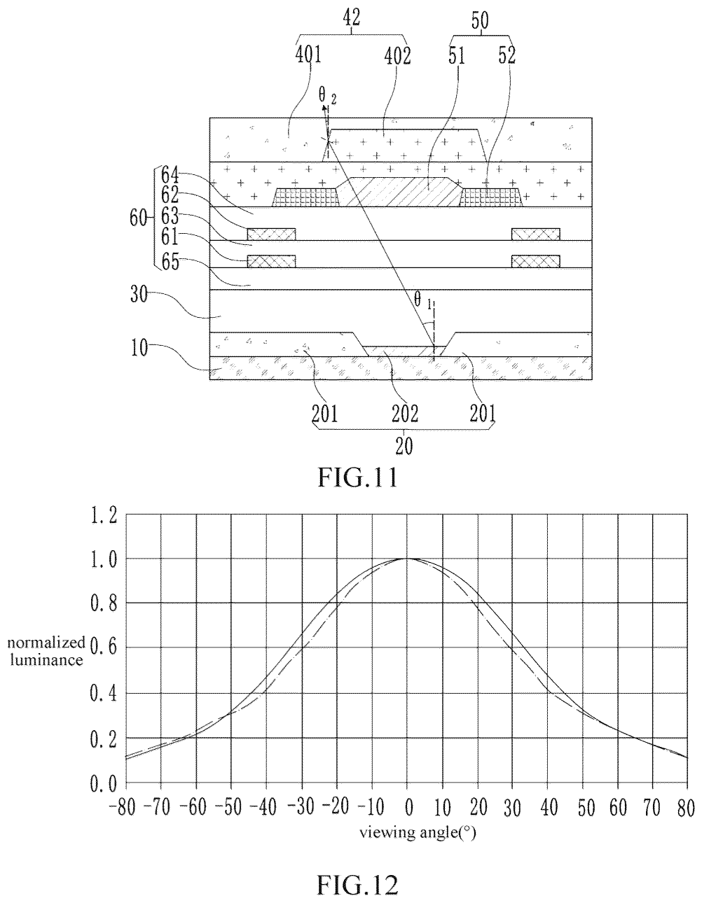

As shown in FIG. 11, the difference from FIG. 10 is that the angle between the side surface and the bottom surface of the first refractive unit 401 of the second optical path regulation layer 42 is greater than 90 degrees, and the angle between the exit light and the normal line of the side surface of the first refractive unit 401 of the second optical path regulation layer 42 is less than 40 degrees. Although the angle between the normal line of the side surface of the first refractive unit 401 and the horizontal direction is negative, the incident angle θ1 is less than the critical angle. Thus, the exit light of the sub-pixel will be refracted when being incident onto the side surface of the first refractive unit 401, so that the exit angle θ2 of the exit light becomes smaller. Therefore, the converging effect of the exit light is still produced, which can accelerate the luminance decay of a certain monochromatic light at a small viewing angle.

In FIG. 12, the solid line is the curve of luminance change with viewing angle when the second optical path regulation layer 42 is not provided. The dotted line is the curve of luminance change with viewing angle when the second optical path regulation layer 42 in FIG. 10 and FIG. 11 is arranged. It can be seen that the luminance decay at a small viewing angle is indeed accelerated.

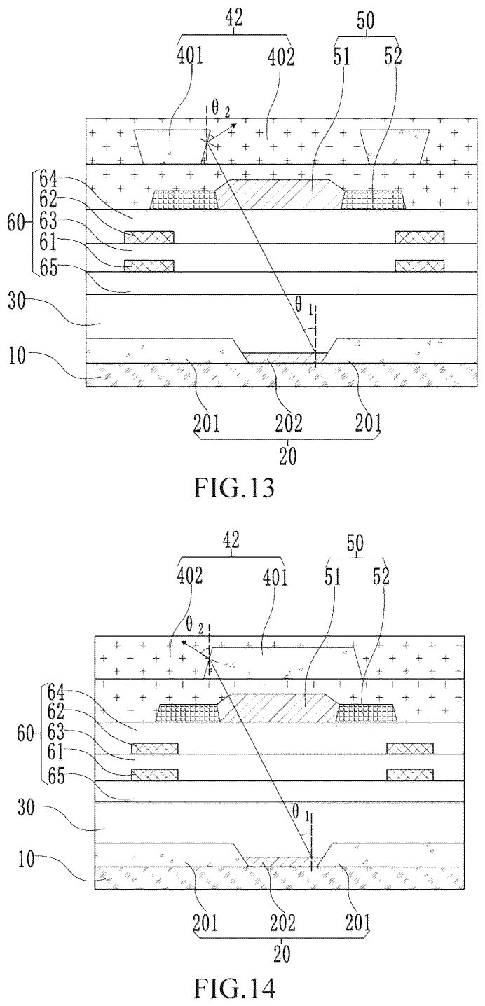

As shown in FIG. 13, the difference from FIG. 11 is that the angle between the exit light and the normal line of the side surface of the first refractive unit 401 of the second optical path regulation layer 42 is greater than 40 degrees and less than 90 degrees. The angle between the normal line of the side surface of the first refractive unit 401 and the horizontal direction is negative, and the incident angle θ1 of the exit light is greater than the critical angle. Therefore, when the exit light of the sub-pixel is incident onto the side surface of the first refractive unit 401 from the second refractive unit 402, total reflection occurs, so that the exit angle θ2 of the exit light becomes larger, resulting in the diverging effect of the exit light. This can slow down the luminance decay of a certain monochromatic light at a small viewing angle.

As shown in FIG. 14, the difference from FIG. 13 is that the orthographic projection of the first refractive unit 401 of the second optical path regulation layer 42 on the driving backplane 10 covers the orthographic projection of at least one sub-pixel on the base substrate, and the angle between the side surface and the bottom surface of the first refractive unit 401 of the second optical path regulation layer 42 is less than 90 degrees. The incident angle θ1 of the exit light is less than the critical angle. When the exit light is incident onto the side surface of the first refractive unit 401 from the second refractive unit 402, it will be refracted, so that the exit angle θ2 of the exit light becomes larger, and the diverging effect of the exit light is produced. This can slow down the luminance decay of a certain monochromatic light at a small viewing angle.

In FIG. 15, the solid line is the curve of luminance variation with viewing angle when the second optical path regulation layer 42 is not provided. The dotted line is the curve of luminance variation with viewing angle when the second optical path regulation layer 42 in FIG. 13 and FIG. 14 is arranged. It can be seen that the luminance decay at the small viewing angle is indeed slowed down.

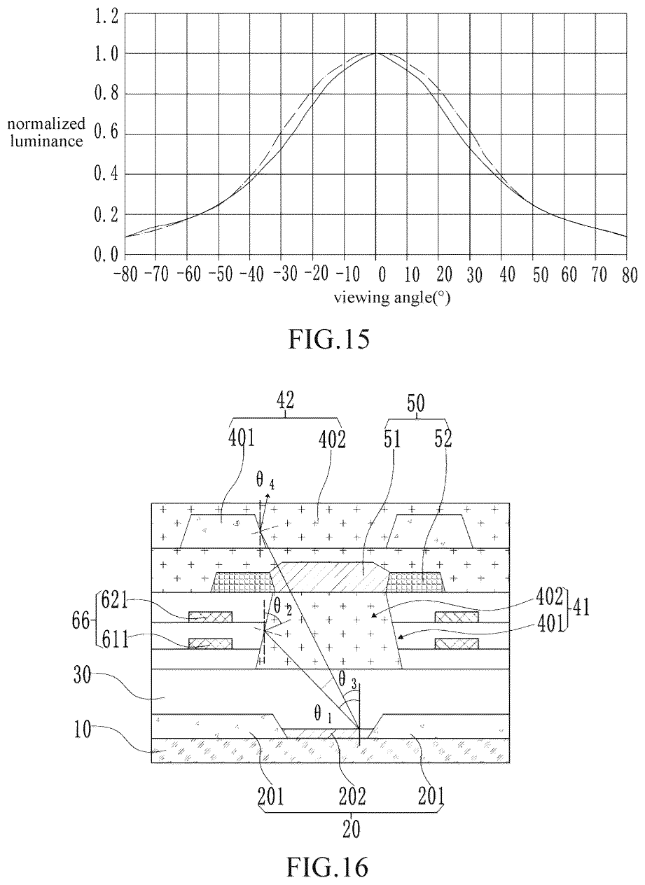

As shown in FIG. 16, the optical path regulation layer may include a first optical path regulation layer 41 and a second optical path regulation layer 42. The first optical path regulation layer 41 is arranged on the side of the color filter layer 50 close to the driving backplane 10. The first optical path regulation layer 41 adopts the structure of the first optical path regulation layer 41 shown in FIG. 7. The structure of the first optical path regulation layer 41 in FIG. 7 has been described in detail before, so it will not be repeated. The second optical path regulation layer 42 is arranged on the side of the color filter layer 50 away from the driving backplane 10. The second optical path regulation layer 42 adopts the structure of the second optical path regulation layer 42 shown in FIG. 10. The structure of the second optical path regulation layer 42 in FIG. 10 has been described in detail above, so it will not be described again.

The incident angle θ1 of one of the exit light rays is greater than the critical angle, and the angle between the side surface and the bottom surface of the first refractive unit 401 of the first optical path regulation layer 41 is greater than 90 degrees. Therefore, the exit light of the sub-pixel will be totally reflected when being incident onto the side surface of the first refractive unit 401 of the first optical path regulation layer 41. Thus, the exit angle θ2 of the exit light becomes larger, resulting in the diverging effect of the exit light, which can slow down the luminance decay of a certain monochromatic light at full viewing angle. The incident angle θ3 of another exit light ray is also greater than the critical angle, and the angle between the side surface and the bottom surface of the first refractive unit 401 of the second light path regulation layer 42 is less than 90 degrees. Therefore, the exit light of the sub-pixel will be totally reflected when being incident onto the side surface of the first refractive unit 401 of the first light path regulation layer 41. Thus, the exit angle θ4 of the exit light is reduced, resulting in the converging effect of the exit light, which can accelerate the luminance decay of a certain monochromatic light at a small viewing angle.

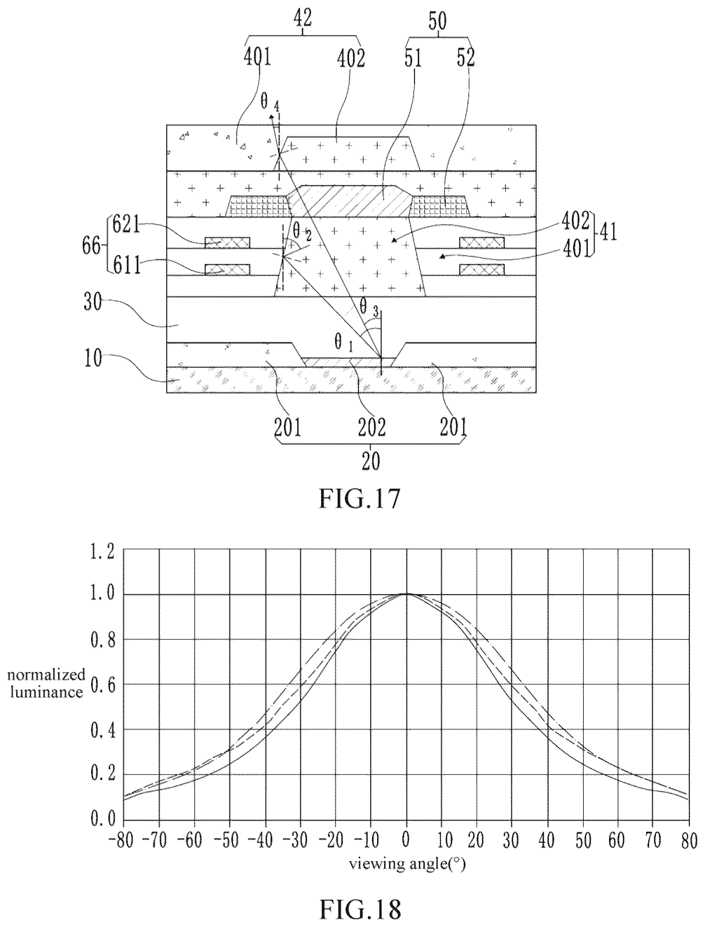

As shown in FIG. 17, the difference from FIG. 16 is that the second light path regulation layer 42 adopts the structure of the second light path regulation layer 42 shown in FIG. 11. The structure of the second light path regulation layer 42 in FIG. 11 has been described in detail above, so it will not be repeated.

The incident angle θ1 of one of the exit light rays is greater than the critical angle, and the angle between the side surface and the bottom surface of the first refractive unit 401 of the first optical path regulation layer 41 is greater than 90 degrees. Therefore, the exit light of the sub-pixel will be totally reflected when being incident onto the side surface of the first refractive unit 401 of the first optical path regulation layer 41. Thus, the exit angle θ2 of the exit light becomes larger, and the diverging effect of the exit light is produced, which can slow down the luminance decay of a certain monochromatic light at full viewing angle. The incident angle θ3 of another exit light ray is less than the critical angle, the angle between the side surface and the bottom surface of the first refractive unit 401 of the second optical path regulation layer 42 is greater than 90 degrees, and the angle between the exit light and the normal line of the side surface of the first refractive unit 401 of the second optical path regulation layer 42 is less than 40 degrees. Therefore, the exit light of the sub-pixel will be refracted when being incident onto the side surface of the first refractive unit 401 of the first optical path regulation layer 41. Thus, the exit angle θ4 of the exit light is reduced, and the converging effect of the exit light is produced, which can accelerate the luminance decay of a certain monochromatic light at a small viewing angle.

In FIG. 18, the solid line is the curve of luminance variation with viewing angle when the optical path regulation layer is not provided. The dotted line is the curve of luminance variation with viewing angle when the first optical path regulation layer 41 is arranged. The first optical path regulation layer 41 can slow down the luminance decay of a certain monochromatic light at full viewing angle. The dotted line is the curve of luminance variation with viewing angle when the first optical path regulation layer 41 and the second optical path regulation layer 42 are both arranged. It can be seen that the luminance decay at a large viewing angle is indeed slowed down.

It can be understood that the first optical path regulation layer 41 can slow down the luminance decay of a certain monochromatic light at full viewing angle, and the second optical path regulation layer 42 can speed up the luminance decay of a certain monochromatic light at a small viewing angle. After the accelerated luminance decay of a certain monochromatic light at a small viewing angle is offset by the slowed luminance decay at full viewing angle, the slowed luminance decay of the certain monochromatic light at a large viewing angle can be achieved.

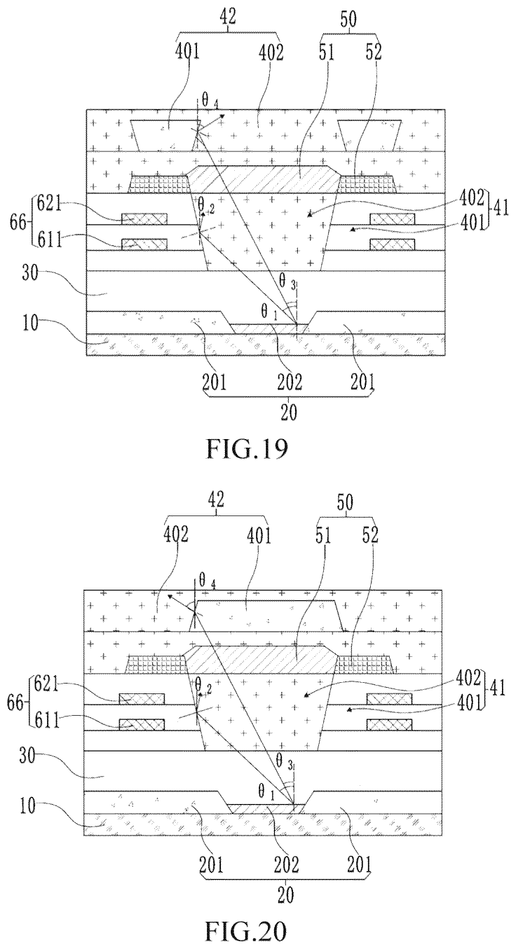

As shown in FIG. 19, the optical path regulation layer may include a first optical path regulation layer 41 and a second optical path regulation layer 42. The first optical path regulation layer 41 is arranged on the side of the color filter layer 50 close to the driving backplane 10. The first optical path regulation layer 41 adopts the structure of the first optical path regulation layer 41 shown in FIG. 6. The structure of the first optical path regulation layer 41 in FIG. 6 has been described in detail before, so it will not be repeated. The second optical path regulation layer 42 is arranged on the side of the color filter layer 50 away from the driving backplane 10. The second optical path regulation layer 42 adopts the structure of the second optical path regulation layer 42 shown in FIG. 13. The structure of the second optical path regulation layer 42 in FIG. 13 has been described in detail before, so it will not be repeated.

The angle between the side surface and the bottom surface of the first refractive unit 401 of the first optical path regulation layer 41 is larger than 90 degrees, and the incident angle θ1 of one of the exit light rays is greater than the critical angle. Thus, the exit light of the sub-pixel will be totally reflected when being incident onto the side surface of the first refractive unit 401 of the first optical path regulation layer 41, so that the exit angle θ2 of the exit light becomes smaller, and the converging effect of the exit light is produced. This can accelerate the luminance decay of a certain monochromatic light at full viewing angle. The angle between the side surface and the bottom surface of the first refractive unit 401 of the second optical path regulation layer 42 is greater than 90 degrees, and the incident angle θ3 of another exit light ray is also greater than the critical angle. Thus, the exit light of the sub-pixel will be totally reflected when being incident onto the side surface of the first refractive unit 401 of the first optical path regulation layer 41, so that the exit angle θ4 of the exit light becomes larger, and the diverging effect of the exit light is produced. This can slow down the luminance decay of a certain monochromatic light at a small viewing angle.

As shown in FIG. 20, the difference from FIG. 19 is that the second optical path regulation layer 42 adopts the structure of the second optical path regulation layer 42 shown in FIG. 14. The structure of the second optical path regulation layer 42 in FIG. 14 has been described in detail above, so it will not be described again.

The angle between the side surface and the bottom surface of the first refractive unit 401 of the first optical path regulation layer 41 is larger than 90 degrees, and the incident angle θ1 of the exit light incident on the first optical path regulation layer 41 is greater than the critical angle. Therefore, the exit light of the sub-pixel will be totally reflected when being incident onto the side surface of the first refractive unit 401 of the first optical path regulation layer 41, so that the exit angle θ2 of the exit light becomes smaller, resulting in the converging effect of the exit light, which can accelerate the luminance decay of a certain monochromatic light at full viewing angle. The angle between the exit light and the normal line of the side surface of the first refractive unit 401 of the second optical path regulation layer 42 is less than 40 degrees, and the incident angle θ3 of the exit light incident on the second optical path regulation layer 42 is less than the critical angle. Therefore, the exit light of the sub-pixel will be refracted when being incident onto the side surface of the first refractive unit 401 of the first optical path regulation layer 41, so that the exit angle θ4 of the exit light is reduced, resulting in the diverging effect of the exit light, which can slow down the luminance decay of a certain monochromatic light at a small viewing angle.

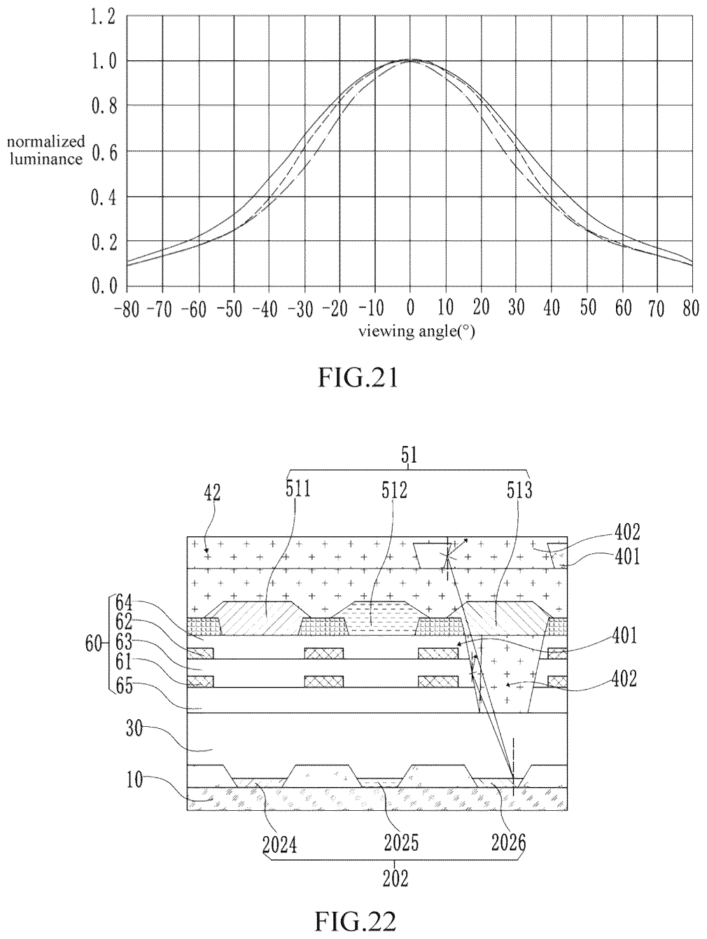

In FIG. 21, the solid line is the curve of luminance variation with viewing angle when the optical path regulation layer is not provided. The dotted line is the curve of luminance variation with viewing angle when the first optical path regulation layer 41 is arranged. The first optical path regulation layer 41 can slow down the luminance decay of a certain monochromatic light at full viewing angle. The dotted line is the curve of luminance variation with viewing angle when the first optical path regulation layer 41 and the second optical path regulation layer 42 are both arranged. It can be seen that the luminance decay at a large viewing angle is indeed accelerated.

It can be understood that the first optical path regulation layer 41 can accelerate the luminance decay of a certain monochromatic light at full viewing angle, and the second optical path regulation layer 42 can slow down the luminance decay of a certain monochromatic light at a small viewing angle. After the slowed luminance decay of a certain monochromatic light at a small viewing angle is offset by the accelerated luminance decay at the full viewing angle, the accelerated luminance decay of a certain monochromatic light at a large viewing angle can be achieved.

The display panel provided by the embodiments of the present disclosure is further described below in conjunction with specific application scenarios.

As shown in FIG. 22, the sub-pixel 202 usually includes a red sub-pixel 2024, a green sub-pixel 2025, and a blue sub-pixel 2026, and the filter unit 51 usually includes a red filter unit 511, a green filter unit 512, and a blue filter unit 513. The problem of color deviation of the color deviation trajectory at white light viewing angle toward a single large viewing angle, for example, the display panel becoming severely blue at the large viewing angle, results in a large color deviation value of the displayed image.

The optical path regulation structure shown in FIG. 19 or FIG. 20 may be introduced for the blue sub-pixel. Specifically, a first optical path regulation layer 41 is provided on the side of the blue filter unit 513 close to the driving backplane 10, and a second optical path regulation layer 42 is provided on the side of the blue filter unit 513 close to the driving backplane 10. The first optical path regulation layer 41 can accelerate the luminance decay of the blue light at full viewing angle. The second optical path regulation layer 42 can slow down the luminance decay of the blue light at a small viewing angle. Thus, after the slowed luminance decay of the blue light at a small viewing angle is offset by the accelerated luminance decay at full viewing angle, the luminance decay of the blue light at a large viewing angle can be accelerated.

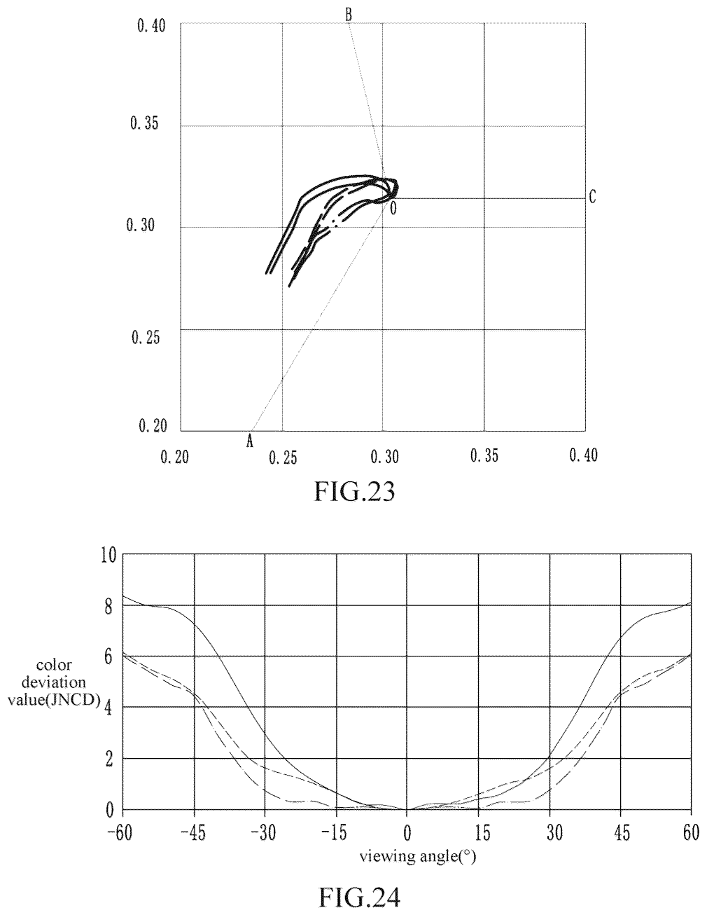

FIG. 23 is a CIE trajectory diagram at the white light viewing angle of the display panel in FIG. 22, and FIG. 24 is a schematic diagram of the color deviation at different viewing angles of the display panel in FIG. 22. It can be seen from FIG. 23 and FIG. 24 that when only the first optical path regulation layer 41 is provided, the luminance decay of the blue light at full viewing angle is accelerated. Although the blueing effect at a large viewing angle is significantly improved and the color deviation value is reduced, the yellowing phenomenon still occurs at a small viewing angle(<25°), resulting in an increase in the color deviation value. When the first optical path regulation layer 41 and the second optical path regulation layer 42 are introduced at the same time, the luminance decay of blue light at a large viewing angle is accelerated. While improving the blueing color deviation of white light at a large viewing angle, it will not cause the yellowing color deviation at a small viewing angle. While reducing the color deviation value of white light at a large viewing angle, it will not cause the deterioration of the color deviation value at a small viewing angle.

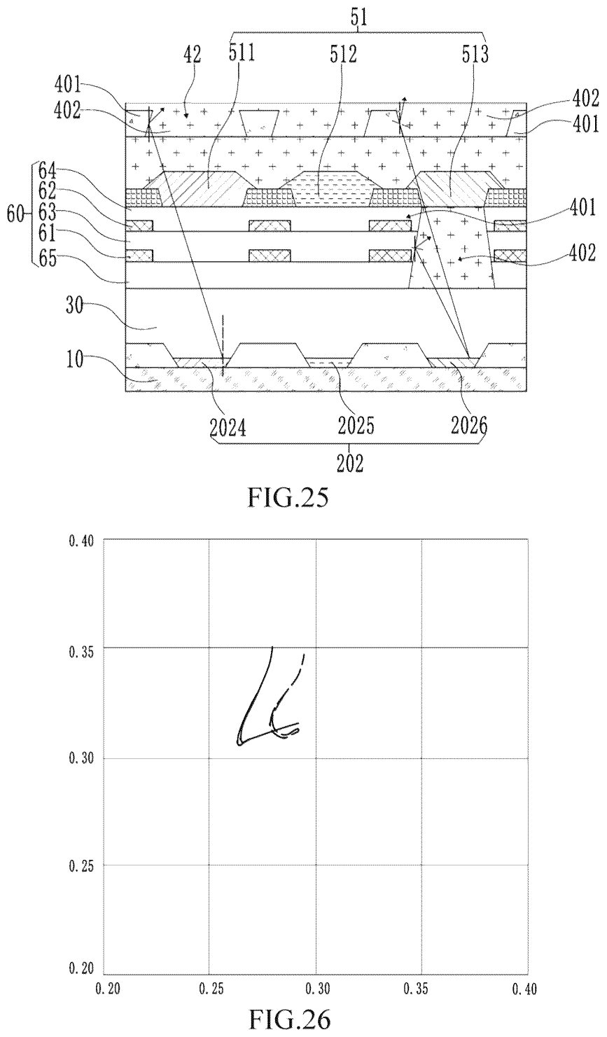

The color deviation problem of the color deviation trajectory at white light viewing angle with an inflection point, such as blueing at a small viewing angle and yellowing at a large viewing angle, both being serious, results in large color deviation values at small and large viewing angles. As shown in FIG. 25, RGB is differentiated by introducing an optical path regulation layer. The second optical path regulation layer 42 shown in FIG. 13 or FIG. 14 is arranged on the side of the red filter unit 511 close to the driving backplane 10. The second optical path regulation layer 42 can slow down the luminance decay of red light at a small viewing angle. The first optical path regulation layer 41 and the second optical path regulation layer 42 shown in FIG. 16 and FIG. 17 are arranged on both sides of the blue filter unit 513. The first optical path regulation layer 41 can slow down the luminance decay of the blue light at full viewing angle. The second optical path regulation layer 42 can accelerate the luminance decay of the blue light at a small viewing angle. Thus, after the accelerated luminance decay of the blue light at a small viewing angle is offset by the slowed luminance decay at full viewing angle, the luminance decay of the blue light at a large viewing angle can be slowed down.

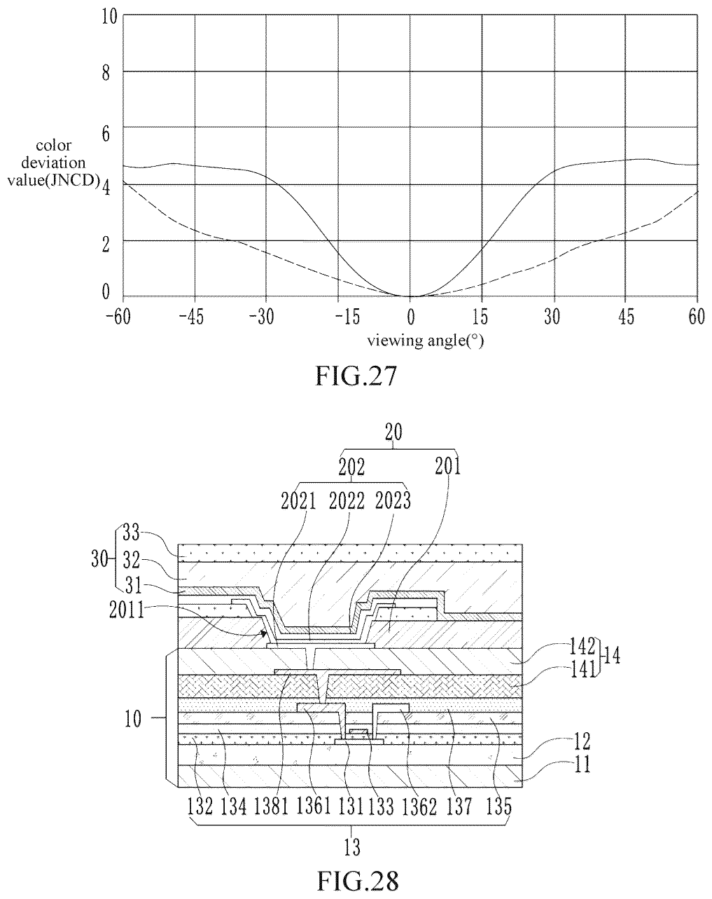

FIG. 26 is a CIE trajectory diagram at the white light viewing angle of the display panel in FIG. 25, and FIG. 27 is a schematic diagram of the color deviation at different viewing angles of the display panel in FIG. 26. After introducing differentiated double-layer optical path regulation layers for sub-pixels of different colors, it can be seen from FIG. 26 that the degree of blueing of the white light at a small viewing angle and yellowing at a large viewing angle are both reduced. It can be seen from FIG. 27 that the color deviation values of the white light at large and small viewing angles are reduced, thereby improving the color deviation of the white light at small and large viewing angles at the same time.

When the OLED display panel displays an image, it is generally achieved by applying driving signals of different sizes to the pixel layer 20 by the driving backplane 10. The driving backplane 10 and the pixel layer 20 constitute a display substrate. The structure of the display substrate according to an embodiment of the present disclosure is described in detail below.

As shown in FIG. 28, the display substrate generally may include a driving backplane 10 and a pixel layer 20. The driving backplane 10 includes a base substrate 11, a driving circuit layer 13, and a planarization layer group 14. The driving circuit layer 13 is arranged on one side of the base substrate 11. The planarization layer group 14 is arranged on the side of the driving circuit layer 13 away from the base substrate 11. The pixel layer 20 is arranged on the side of the planarization layer group 14 away from the base substrate 11. In addition, the display substrate may also include a first buffer layer 12, and the first buffer layer 12 is arranged between the base substrate 11 and the driving circuit layer 13.

The base substrate 11 may be a base substrate of inorganic material or organic material. For example, in an embodiment of the present disclosure, the material of the base substrate 11 may be a glass material such as soda-lime glass, quartz glass, sapphire glass, or a metal material such as stainless steel, aluminum, nickel, etc.

In another embodiment of the present disclosure, the base substrate 11 may also be a flexible substrate. For example, the material of the base substrate 11 may be polyimide (PI). The base substrate 11 may also be a composite of multiple layers of materials. For example, in an embodiment of the present disclosure, the base substrate 11 may include a bottom film layer, a pressure-sensitive adhesive layer, a first polyimide layer, and a second polyimide layer stacked in sequence.

In the present disclosure, the driving circuit layer 13 is provided with a driving circuit for driving sub-pixels. In the driving circuit layer 13, any driving circuit may include a transistor and a storage capacitor. Further, the transistor may be a thin film transistor. The thin film transistor may be selected from a top gate thin film transistor, a bottom gate thin film transistor, or a dual gate thin film transistor. The top gate thin film transistor is taken as an example, where the driving circuit layer 13 may include an active layer 131, a gate insulation layer 132, a gate 133, and a first source-drain metal layer.

The active layer 131 is arranged on one side of the base substrate 11 and is located in the display area 201. The material of the active layer 131 may be an amorphous silicon semiconductor material, a low temperature polycrystalline silicon semiconductor material, a metal oxide semiconductor material, an organic semiconductor material, or other types of semiconductor materials. Therefore, the thin film transistor may be an N-type thin film transistor or a P-type thin film transistor. The active layer 131 may include a channel region and two doping regions of different doping types located on both sides of the channel region.

The gate insulation layer 132 may cover the active layer 131 and the base substrate 11. The material of the gate insulation layer 132 is an insulation material such as silicon oxide.

The gate 133 is arranged in the display area 201. The gate 133 is arranged on the side of the gate insulation layer 132 away from the base substrate 11, and is directly facing the active layer 131. That is, the projection of the gate 133 on the base substrate 11 is located within the projection range of the active layer 131 on the base substrate 11. For example, the projection of the gate 133 on the base substrate 11 coincides with the projection of the channel region of the active layer 131 on the base substrate 11.

The driving circuit layer 13 also includes an interlayer insulation layer 134, which covers the gate 133 and the gate insulation layer 132. The driving circuit layer 13 also includes an interlayer dielectric layer 135, which is arranged on the side of the interlayer insulation layer 134 away from the base substrate 11. The interlayer insulation layer 134 and the interlayer dielectric layer 135 are both insulation materials, but the materials of the interlayer insulation layer 134 and the interlayer dielectric layer 135 may be different.

The first source-drain metal layer is arranged on the surface of the interlayer dielectric layer 135 away from the base substrate 11. The first source-drain metal layer includes a first source 1361 and a drain 1362. The first source 1361 and the drain 1362 are arranged in the display area 201 and connected to the active layer 131. For example, the first source 1361 and the drain 1362 are respectively connected to the two doping regions of the corresponding active layer 131 through via holes.

A protective layer 137 is arranged on the side of the first source-drain metal layer away from the base substrate 11, and the protective layer 137 covers the first source-drain metal layer. A planarization layer group 14 is arranged on the side of the first source-drain metal layer away from the base substrate 11. The planarization layer group 14 is arranged on the side of the protective layer 137 away from the base substrate 11. The planarization layer group 14 covers the protective layer 137. The surface of the planarization layer group 14 away from the base substrate 11 is a plane.

Specifically, the planarization layer group 14 may include a first planarization layer 241, and the first planarization layer 241 covers the protective layer 137. The display substrate may also include a second source-drain metal layer. A second planarization layer 242 is provided on the side of the second source-drain metal layer away from the base substrate 11. The second planarization layer 242 covers the second source-drain metal layer and the side of the first planarization layer 241 away from the base substrate 11. The second source-drain metal layer includes a second source electrode 1381, and the second source electrode 1381 is connected to the first source electrode 1361 through a via hole.

A pixel layer 20 may be provided on the side of the planarization layer group 14 away from the base substrate 11. The pixel layer 20 includes a pixel definition layer 201 and a plurality of sub-pixels 202. The pixel definition layer 201 has a plurality of pixel openings 2011. The plurality of sub-pixels 202 is respectively provided in the plurality of pixel openings 2011. The plurality of sub-pixels 202 is arrayed and distributed on the side of the driving backplane 10 away from the base substrate 11. The specific sub-pixels 202 may be located on the side of the planarization layer group 14 away from the base substrate 11. It should be noted that the sub-pixels 202 may include red sub-pixels, green sub-pixels, and blue sub-pixels according to different emitting colors.

The pixel layer 20 may include a plurality of pixel electrodes 2021, a light-emitting layer 2022, and a common electrode 2023. The pixel electrode 2021 is located on the surface of the driving backplane 10 away from the base substrate 11. The light-emitting layer 2022 is located on the surface of the pixel electrode 2021 away from the base substrate 11. The common electrode 2023 is located on the surface of the light-emitting layer 2022 away from the base substrate 11.

The pixel electrode 2021 is connected to the first source 1361 or the second source 1381. When the driving circuit layer 13 includes only the first source 1361 and the first planarization layer 241, the pixel electrode 2021 is connected to the first source 1361 through the via hole on the first planarization layer 241, and the pixel definition layer 201 is arranged to cover the first electrode 161 and the first planarization layer 241. When the driving circuit layer 13 also includes a second source-drain metal layer and a second planarization layer 242, the pixel electrode 2021 is connected to the second source 1381 through the via hole on the second planarization layer 242, and the pixel definition layer 201 is arranged to cover the second source-drain metal layer and the second planarization layer 242.

The common electrode 2023 may be used as a cathode, the pixel electrode 2021 may be used as an anode, the pixel electrode 2021 is connected to the positive electrode of the power supply, and the common electrode 2023 is connected to the negative electrode of the power supply. The light-emitting layer 2022 may be driven to emit light by applying a signal through the pixel electrode 2021 and the common electrode 2023 so as to display an image. The specific light-emitting principle is not described in detail here. The light-emitting layer 2022 may include an electroluminescent organic light-emitting material. For example, the light-emitting layer 2022 may include an auxiliary layer and a light-emitting material layer sequentially stacked on the pixel electrode 2021. Generally, a pattern area is arranged on the mask plate, and an auxiliary layer for sub-pixels of different colors and a light-emitting layer 2022 for sub-pixels of different colors are formed by evaporation and other processes.

In addition, the display substrate of the present disclosure may further include an encapsulation layer 30, which is arranged on the side of the pixel layer 20 away from the base substrate 11, so that the pixel layer 20 is covered to prevent water and oxygen corrosion. The encapsulation layer 30 may be a single-layer or multi-layer structure, and the material of the encapsulation layer 30 may include organic or inorganic materials, which are not specifically limited here.

In an embodiment, the encapsulation layer 30 may include a first inorganic encapsulation layer 31, an organic encapsulation layer 32, and a second inorganic encapsulation layer 33. The first inorganic encapsulation layer 31 is arranged on the side of the pixel layer 20 away from the base substrate 11. The organic encapsulation layer 32 is arranged on the side of the first inorganic encapsulation layer 31 away from the base substrate 11. The second inorganic encapsulation layer 33 is arranged on the side of the organic encapsulation layer 32 away from the base substrate 11. The second touch part is usually arranged on the side of the second inorganic encapsulation layer 33 away from the base substrate 11.

An embodiment of the present disclosure provides a display device, which may include a display panel in any one of the above embodiments of the present disclosure. The specific structure of the display panel has been described in detail above, so it will not be repeated here.

It should be noted that, in addition to the display panel, the display device also includes other necessary components and parts. Taking the display as an example, the display device includes a housing, a circuit board, a power cord, etc. Those skilled in the art can make corresponding supplements according to the specific use requirements of the display device, which will not be repeated here.

The display device may be a traditional electronic device, such as a mobile phone, a computer, a television, and a camcorder, or may be an emerging wearable device, such as a virtual reality device and an augmented reality device, which are not listed here one by one.

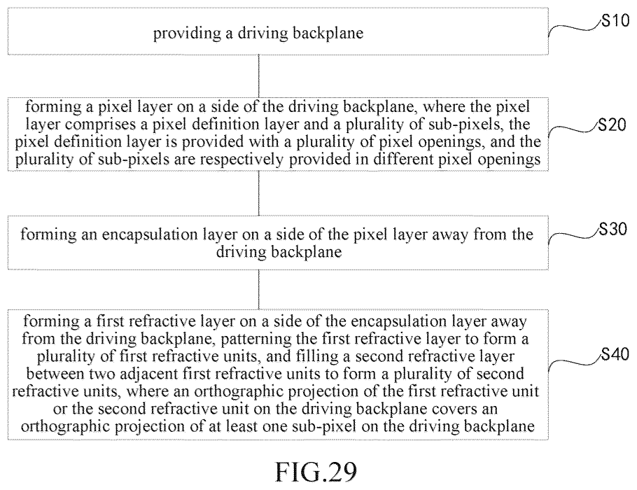

An embodiment of the present disclosure also provides a method for manufacturing the above-mentioned display panel. As shown in FIG. 29, the method includes steps S10, S20, S30, and S40.

Step S10, providing a driving backplane.

Step S20, forming a pixel layer on a side of the driving backplane, where the pixel layer includes a pixel definition layer and a plurality of sub-pixels, the pixel definition layer is provided with a plurality of pixel openings, and the plurality of sub-pixels is respectively provided in different pixel openings.

Step S30, forming an encapsulation layer on the side of the pixel layer away from the driving backplane.

Step S40, forming a first refractive layer on the side of the encapsulation layer away from the driving backplane, patterning the first refractive layer to form a plurality of first refractive units, and filling a second refractive layer respectively between two adjacent first refractive units to form a plurality of second refractive units, where the orthographic projection of the first refractive unit or the second refractive unit on the driving backplane covers the orthographic projection of at least one sub-pixel on the base substrate.

In step S40, a first refractive layer is formed on the side of the encapsulation layer away from the driving backplane, and the first refractive layer is patterned to form a plurality of first refractive units.

It should be noted that the angle between the side surface and the bottom surface of the first refractive unit is greater than or less than 90 degrees.

When the first refractive layer is positive photoresist, patterning the first refractive layer to form the plurality of first refractive units includes: exposing and developing the area of the first refractive layer directly facing the sub-pixel, where the residue increases as the etching depth increases during the development and patterning process, so that the cross section of the first refractive unit is a positive trapezoid, that is, the angle between the side surface and the bottom surface of the first refractive unit is less than 90 degrees.

When the first refractive layer is negative photoresist, patterning the first refractive layer to form the plurality of first refractive units includes: exposing and developing the area of the first refractive layer directly facing the pixel definition layer at the periphery of the sub-pixel, where as the etching depth increases during the development process, the loss of the film layer to be retained increases, resulting in the cross-section of the first refractive unit being an inverted trapezoid, that is, the angle between the side surface and the bottom surface of the first refractive unit is greater than 90 degrees.

In step S40, the second refractive layer is filled respectively between two adjacent first refractive units to form the plurality of second refractive units.

The second refractive layer is deposited between two adjacent first refractive units by the way of inkjet printing.

The plurality of first refractive units and the plurality of second refractive units constitute the optical path regulation layer. The first refractive layer may be a touch layer. According to the requirements for slowing down or accelerating the luminance decay, the material of the first refractive layer is selected to be positive photoresist or negative photoresist. The second passivation layer, the first passivation layer, and the second buffer layer located between two adjacent touch groups are photoetched in a corresponding way to form the first refractive unit.

The width of the touch group located on the touch layer is usually 3 microns. Considering the accuracy of the etching process, the width of the first refractive unit is usually greater than or equal to 7 microns. Specifically, the distance between the edge of the orthographic projection of the touch group 66 on the driving backplane and the edge of the orthographic projection of the first refractive unit on the driving backplane is greater than 2 microns. The refraction effect of the first refractive unit can be ensured without affecting the touch function of the touch layer.

The spacing between adjacent sub-pixels is usually 18-23 microns. Thus, the side with a smaller width of the second refractive unit can be expanded by more than 10 microns than the light-emitting area of the sub-pixel. Generally, the center line of the sub-pixel is coinciding with the center line of the second refractive unit. Therefore, it is usually that the distance between the edge of the orthographic projection on the driving backplane of the side with a smaller width of the second refractive unit and the edge of the orthographic projection on the driving backplane of the side away from the driving backplane of the sub-pixel is greater than 5 microns. This effectively ensures that the exit light of the sub-pixel area is incident into the second refractive unit first.

After considering the specification and practicing the content disclosed herein, those skilled in the art will easily think of other embodiments of the present disclosure. The present application is intended to cover any variation, use or adaptation of the present disclosure, which follows the general principles of the present disclosure and includes common knowledge or customary technical means in the technical field that are not disclosed in the present disclosure. The description and examples are to be regarded as exemplary only, and the true scope and spirit of the present disclosure are indicated by the appended claims.

1. A display panel, comprising:
a driving backplane;
a pixel layer, comprising a pixel definition layer and a plurality of sub-pixels of different colors, wherein the pixel definition layer is located on a side of the driving backplane, the pixel definition layer is provided with a plurality of pixel openings, and the plurality of sub-pixels is respectively located in different pixel openings;
an encapsulation layer, located on a side of the pixel layer away from the driving backplane;
an optical path regulation layer, located on a side of the encapsulation layer away from the driving backplane, wherein the optical path regulation layer comprises a plurality of first refractive units, an angle between a side surface and a bottom surface of the first refractive unit is greater than or less than 90 degrees, a second refractive unit is provided between two adjacent first refractive units, an orthographic projection of the first refractive unit or the second refractive unit on the driving backplane covers an orthographic projection of at least one sub-pixel on the driving backplane, a refractive index of the second refractive unit is greater than a refractive index of the first refractive unit, and an exit angle of an exit light of the sub-pixel becomes larger or smaller after the exit light passes through an interface between a side surface of the first refractive unit and a side surface of the second refractive unit.

2. The display panel according to claim 1, wherein the display panel further comprises a color filter layer, the color filter layer is located on a side of the encapsulation layer away from the driving backplane, the optical path regulation layer is located on a side of the color filter layer away from and/or close to the driving backplane, the color filter layer comprises filter units of different colors and a black matrix located at a periphery of the filter unit, and an orthographic projection of the filter unit of a color on the driving backplane covers an orthographic projection of the first refractive unit or the second refractive unit corresponding to the sub-pixel of the same color on the driving backplane.

3. The display panel according to claim 2, wherein the optical path regulation layer comprises:
a first optical path regulation layer located on a side of the color filter layer close to the driving backplane, wherein an orthographic projection of the second refractive unit of the first optical path regulation layer on the driving backplane covers an orthographic projection of at least one sub-pixel on the driving backplane, and an angle between a side surface and a bottom surface of the first refractive unit of the first optical path regulation layer is less than 90 degrees.

4. The display panel according to claim 2, wherein the optical path regulation layer comprises:
a first optical path regulation layer located on a side of the color filter layer close to the driving backplane, wherein an orthographic projection of the second refractive unit of the first optical path regulation layer on the driving backplane covers an orthographic projection of at least one sub-pixel on the driving backplane, and an angle between a side surface and a bottom surface of the first refractive unit of the first optical path regulation layer is greater than 90 degrees.

5. The display panel according to claim 2, wherein the optical path regulation layer comprises:
a second optical path regulation layer located on a side of the color filter layer away from the driving backplane, wherein an orthographic projection of the second refractive unit of the second optical path regulation layer on the driving backplane covers an orthographic projection of at least one sub-pixel on the driving backplane, and an angle between a side surface and a bottom surface of the first refractive unit of the second optical path regulation layer is less than 90 degrees.

6. The display panel according to claim 2, wherein the optical path regulation layer comprises:
a second optical path regulation layer located on a side of the color filter layer away from the driving backplane, wherein an orthographic projection of the second refractive unit of the second optical path regulation layer on the driving backplane covers an orthographic projection of at least one sub-pixel on the driving backplane, an angle between a side surface and a bottom surface of the first refractive unit of the second optical path regulation layer is greater than 90 degrees, and an angle between the exit light and a normal line of a side surface of the first refractive unit of the second optical path regulation layer is less than 40 degrees.

7. The display panel according to claim 2, wherein the optical path regulation layer comprises:
a second optical path regulation layer located on a side of the color filter layer away from the driving backplane, wherein an orthographic projection of the second refractive unit of the second optical path regulation layer on the driving backplane covers an orthographic projection of at least one sub-pixel on the driving backplane, an angle between a side surface and a bottom surface of the first refractive unit of the second optical path regulation layer is greater than 90 degrees, and an angle between the exit light and a normal line of a side surface of the first refractive unit of the second optical path regulation layer is greater than 40 degrees and less than 90 degrees.

8. The display panel according to claim 2, wherein the optical path regulation layer further comprises:
a second optical path regulation layer located on a side of the color filter layer away from the driving backplane, wherein an orthographic projection of the first refractive unit of the second optical path regulation layer on the driving backplane covers an orthographic projection of at least one sub-pixel on the driving backplane, and an angle between a side surface and a bottom surface of the first refractive unit of the second optical path regulation layer is less than 90 degrees.

9. The display panel according to claim 1, wherein the first optical path regulation layer is a touch layer, the touch layer comprises a plurality of touch groups, and the plurality of touch groups is respectively wrapped in the plurality of first refractive units.

10. The display panel according to claim 8, wherein a distance between an edge of an orthographic projection of the touch group on the driving backplane and an edge of an orthographic projection of the first refractive unit on the driving backplane is greater than 2 microns.

11. The display panel according to claim 1, wherein a distance between an edge of an orthographic projection on the driving backplane of a side with a smaller width of the second refractive unit and an edge of an orthographic projection on the driving backplane of a side away from the driving backplane of the sub-pixel is greater than 5 microns.

12. The display panel according to claim 1, wherein the refractive index of the first refractive unit is 1.3-1.5, and the refractive index of the second refractive unit is 1.7-1.9.

13. The display panel according to claim 1, wherein a material of the first refractive unit is positive photoresist or negative photoresist.

14. The display panel according to claim 1, wherein a thickness of the second refractive unit is greater than a thickness of the first refractive unit, sides of the second refractive units close to the driving backplane are located on the same plane, a side of the second refractive unit away from the driving backplane is higher than the first refractive unit, and two adjacent second refractive units are connected and cover a side of the first refractive unit away from the driving backplane.

15. The display panel according to claim 14, wherein the thickness of the first refractive unit is 2-3 microns, and the thickness of the second refractive unit is 3-5 microns.

16. The display panel according to claim 9, wherein
the touch layer comprises a first touch layer and a second touch layer, a first passivation layer is provided on a side of the first touch layer away from the driving backplane, the second touch layer is located on a side of the first passivation layer away from the driving backplane, and a second passivation layer is provided on a side of the second touch layer away from the driving backplane; and
the first touch layer comprises a first touch part, the second touch layer comprises a second touch part, and the first touch part and the second touch part constitute the touch group.

17. A display device, comprising a display panel, wherein the display panel comprises:
a driving backplane;
a pixel layer, comprising a pixel definition layer and a plurality of sub-pixels of different colors, wherein the pixel definition layer is located on a side of the driving backplane, the pixel definition layer is provided with a plurality of pixel openings, and the plurality of sub-pixels is respectively located in different pixel openings;
an encapsulation layer, located on a side of the pixel layer away from the driving backplane;
an optical path regulation layer, located on a side of the encapsulation layer away from the driving backplane, wherein the optical path regulation layer comprises a plurality of first refractive units, an angle between a side surface and a bottom surface of the first refractive unit is greater than or less than 90 degrees, a second refractive unit is provided between two adjacent first refractive units, an orthographic projection of the first refractive unit or the second refractive unit on the driving backplane covers an orthographic projection of at least one sub-pixel on the driving backplane, a refractive index of the second refractive unit is greater than a refractive index of the first refractive unit, and an exit angle of an exit light of the sub-pixel becomes larger or smaller after the exit light passes through an interface between a side surface of the first refractive unit and a side surface of the second refractive unit.

18. A method for manufacturing a display panel according to claim 1, comprising:
providing a driving backplane;
forming a pixel layer on a side of the driving backplane, wherein the pixel layer comprises a pixel definition layer and a plurality of sub-pixels, the pixel definition layer is provided with a plurality of pixel openings, and the plurality of sub-pixels is respectively provided in different pixel openings;
forming an encapsulation layer on a side of the pixel layer away from the driving backplane; and
forming a first refractive layer on a side of the encapsulation layer away from the driving backplane, patterning the first refractive layer to form a plurality of first refractive units, and filling a second refractive layer between two adjacent first refractive units to form a plurality of second refractive units, wherein an orthographic projection of the first refractive unit or the second refractive unit on the driving backplane covers an orthographic projection of at least one sub-pixel on the driving backplane.

19. The method for manufacturing a display panel according to claim 18, wherein
the first refractive layer is positive photoresist, and
patterning the first refractive layer to form the plurality of first refractive units comprises:
exposing and developing an area of the first refractive layer directly facing the sub-pixel to form the plurality of first refractive units, wherein an angle between a side surface and a bottom surface of the first refractive unit is less than 90 degrees.

20. The method for manufacturing a display panel according to claim 18, wherein
the first refractive layer is negative photoresist, and
patterning the first refractive layer to form the plurality of first refractive units comprises:
exposing and developing an area of the first refractive layer directly facing the pixel definition layer at a periphery of the sub-pixel to form the plurality of first refractive units, wherein an angle between a side surface and a bottom surface of the first refractive unit is greater than 90 degrees.
